(19) United States
(12) Patent Application Publication
(10) Pub. No.: US 2022/0011757 A1
(43) Pub. Date: Jan. 13, 2022

(54) Laser Machine Automatic Operating Method and System

(71) Applicant: CHANGXIN MEMORY TECHNOLOGIES, INC., Hefei City (CN)

(72) Inventor: Yubin LU, Hefei City (CN)

(21) Appl. No.: 17/486,645

(22) Filed: Sep. 27, 2021

Related U.S. Application Data
(63) Continuation of application No. PCT/CN2021/100515, filed on Jun. 17, 2021.

(30) Foreign Application Priority Data
Jun. 22, 2020 (CN) 202010572280.9

(51) Int. Cl. G05B 19/418

(52) U.S. Cl. CPC G05B 19/41865; G05B 2219/45031; G05B 2219/33198; G05B 2219/32252

(57) ABSTRACT

The present application provides laser machine automatic operating method and system, which method comprises: basing on feature information to judge whether a wafer has completed operation on a laser machine, if yes, skipping over the laser machine to perform the next procedure, if not, executing step; processing the wafer on the laser machine, wherein the laser machine generates record information, and the record information is related to operation information of the wafer on the laser machine; and acquiring the record information, and basing on the record information to generate feature information, the feature information serving as judging criteria in step.

### CROSS-REFERENCE TO RELATED APPLICATIONS

The present application is a continuation application of International Patent Application No.: PCT/CN2021/100515, filed on Jun. 17, 2021, which claims the right of priority of the Chinese Patent Application No.: 202010572280.9, filed on Jun. 22, 2020 and entitled “Laser Machine Automatic Operating Method and System”. The entire contents International Patent Application No.: PCT/CN2021/100515 and Chinese Patent Application No.: 202010572280.9 are herein incorporated by reference.

### TECHNICAL FIELD

The present application relates to the field of semiconductor fabrication, and more particularly to a laser machine automatic operating method and a laser machine automatic operating system.

### BACKGROUND

It is usual in the semiconductor fabrication technique to use a laser machine to process wafers, and the wafers enter the next procedure after operation completion at the laser machine. The deficiency of such practice lies in the fact that the currently available laser machine operates offline, so the generation control system cannot be informed of the laser status of a whole batch of wafers, and this might cause the wafers to be repeatedly laser-processed, while repeated laser-processing of wafers might lead to acceptance rate loss of the wafers.

Accordingly, a laser machine automatic operating method and a laser machine automatic operating system are urgently required to deal with the above problem.

### SUMMARY

The present application provides a laser machine automatic operating method that comprises: (a) basing on feature information to judge whether a wafer has completed operation on a laser machine, if yes, skipping over the laser machine to perform the next procedure, if not, executing step (b); (b) processing the wafer on the laser machine, wherein the laser machine generates record information, and the record information is related to operation information of the wafer on the laser machine; and (c) acquiring the record information, and basing on the record information to generate feature information, the feature information serving as judging criteria in step (a).

The present application further provides a laser machine automatic operating system that comprises: a laser machine, for laser-processing a wafer and capable of creating record information that is related to operation information of the wafer on the laser machine; and a control system, for acquiring the record information from the laser machine, basing on the record information to generate feature information, basing on the feature information to judge whether the wafer has performed operation on the laser machine, and generating a control instruction.

### BRIEF DESCRIPTION OF DRAWINGS

In order to more clearly describe the technical solutions exemplified by the present application, accompanying drawings required for use in the embodiments of the present application are briefly introduced below. Apparently, the accompanying drawings described below are merely directed to some embodiments of the present application. Persons ordinarily skilled in the art may further base on these accompanying drawings to acquire other drawings without spending creative effort in the process.

FIG. 1 is a flowchart illustrating one embodiment of the laser machine automatic operating method of the present application; and

FIG. 2 is a block diagram illustrating one embodiment of the laser machine automatic operating system of the present application.

### DESCRIPTION OF EMBODIMENTS

In order to make more lucid and clear the objectives, technical means and advantageous effects of the present application, the present application will be described in greater detail below with reference to the accompanying drawings. As should be understood, the embodiments described in this context are merely partial rather than entire embodiments of the present application, and are not meant to restrict the present application. All other embodiments obtainable by persons skilled in the art on the basis of the embodiments in the present application without spending creative effort shall all fall within the protection scope of the present application.

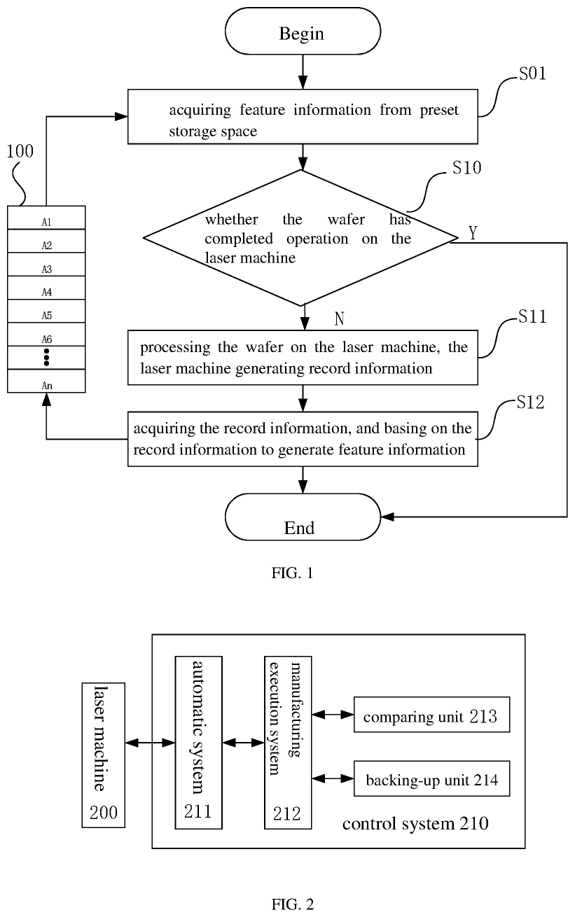

FIG. 1 is a flowchart illustrating one embodiment of the laser machine automatic operating method of the present application. Referring to FIG. 1, the laser machine automatic operating method of the present application comprises the following steps.

Step S10: basing on feature information to judge whether a wafer has completed operation on a laser machine.

In this step the feature information is related to the operation information of the wafer on the laser machine. In this embodiment, the feature information at least includes the inherent information of the wafer and the operation information of the wafer on the laser machine. The inherent information of the wafer is the information of the current batch of wafers as different from other batches of wafers, for instance, the batch number of the wafer. The operation information is employed to record laser operation performed by the wafer on the laser machine. For instance, with regard to a wafer that is required to only perform one laser operation, the operation information corresponding thereto should include the content that the wafer has performed operation on the laser machine; with regard to a wafer that is required to complete several laser operations on the laser machine, the operation information corresponding thereto should include the content that the wafer has completed operation of the laser phase on the laser machine.

The wafer can be associated with its operation information on the laser machine through the inherent information of the wafer. During subsequent operations of the wafer, the inherent information of the wafer can be acquired and used as an index to determine in the feature information the operation circumstance of the wafer on the laser machine.

If the wafer has completed operation on the laser machine, the current procedure ends, and the laser machine is skipped over to perform the next procedure; if the wafer has not completed operation on the laser machine, step S11 is executed.

For example, with regard to a wafer that is required to only perform one laser operation, the feature information is based on to judge whether it has performed laser operation on the laser machine, if yes, the laser machine is skipped over to perform the next procedure, if not, step S11 is executed.

For another example, with regard to a wafer that is required to complete several laser operations on the laser machine, the feature information is based on to judge whether the wafer has completed all laser operations of the laser phase on the laser machine, if yes, the laser machine is skipped over to perform the next procedure; if the wafer has completed only partial laser operations of the laser phase on the laser machine, the judgment is negative, and step S11 is executed; if the wafer has not performed any laser operation on the laser machine, the judgment is also negative, and step S11 is executed.

Step S11: processing the wafer on the laser machine, wherein the laser machine generates record information, and the record information is related to operation circumstance of the wafer on the laser machine.

In this step, after the wafer is processed on the laser machine according to a preset program, the laser machine will automatically generate record information, and the record information is local information of the laser machine. In this embodiment, the record information at least includes the contents of the inherent information of the wafer and the operation information for performing laser operations.

Step S12: acquiring the record information, and basing on the record information to generate feature information, the feature information serving as judging criteria in step S10.

Since the record information is the local information of the laser machine, there might be the circumstance in which the information cannot be identified by other programs or software, so the record information can be analyzed after it is acquired, to generate feature information identifiable by other programs or software.

The feature information generated in this step is the feature information recited in step S10. In the present application, the feature information can be generated only when the wafer has performed laser operation(s) on the laser machine; if the wafer has not performed any operation on the laser machine, no feature information would be generated.

Further, the feature information is stored in a preset storage space 100. In this embodiment, the preset storage space 100 is a storage location provided by the control system. For each wafer or every batch of wafers, after step S12 is performed, its/their feature information is stored in the preset storage space 100. For instance, after step S12 is executed for a certain batch of wafers, the generated feature information A1 is stored in the preset storage space 100; after step S12 is executed for another batch of wafers, the generated feature information A2 is stored in the preset storage space 100, and so on so forth. As shown in FIG. 1, feature information A1˜An are stored in the preset storage space 100, each piece of feature information corresponds to a wafer or a batch of wafers.

Further, prior to step S10 is further included a step S01 of acquiring the feature information from the preset storage space 100. The acquired feature information can be used for the judgment in step S10.

Further, the feature information forms a database retrievable by step S10. In addition, if a problem occurs to the wafer, the user can further base on the record of the database to trace back to the history record of the wafer, so as to facilitate analysis of the problem.

Further, the present application further provides a method of basing on the feature information to judge whether the wafer has completed operation on the laser machine. Judging parameters might slightly differ with regard to a wafer that is required to only perform one laser operation and with regard to a wafer that is required to complete several laser operations on the laser machine.

For example, with regard to a wafer that is required to only perform one laser operation, the inherent information of the wafer is compared with the feature information in the database. It is determined that the wafer has completed operation on the laser machine, if the inherent information matches with the feature information, that is to say, the inherent information is included in the feature information; and it is determined that the wafer has not completed operation on the laser machine, if the inherent information does not match with the feature information, that is to say, the inherent information is not included in the feature information.

For another example, with regard to a wafer that is required to complete several laser operations on the laser machine, the inherent information of the wafer is compared with the feature information in the database. It is determined that the wafer has completed operation on the laser machine, if the inherent information matches with the feature information, that is to say, the inherent information is included in the feature information, and the feature information records that the wafer has completed entire operation; it is determined that the wafer has not completed operation on the laser machine, if the inherent information matches with the feature information, that is to say, the inherent information is included in the feature information, and the feature information records that the wafer has completed partial operation; and it is determined that the wafer has not completed operation on the laser machine, if the inherent information does not match with the feature information, that is to say, the inherent information is not included in the feature information.

Further, database loss might occur in the case the laser machine automatic system is cut power or rebooted, in which case it is required to revamp the feature information of the wafers, and this in turn might lead to circumstances of misjudge, whereby a wafer is laser-operated again. Accordingly, in this embodiment, the laser machine automatic operating method according to the present application further comprises a step of backing up the database. The database is periodically backed up, for instance, weekly, daily or hourly. In the case of data loss, the backed-up data can be restored to the laser machine automatic system, thus avoiding misoperation and greatly enhancing the acceptance rate of the wafers.

The laser machine automatic operating method according to the present application can generate feature information on the basis of local records of the laser machine, hence make use of the feature information to judge whether the wafer has completed laser operation on the laser machine, so that it is avoided to again laser-process the wafer that has completed laser operation, whereby acceptance rate of wafers is greatly enhanced, and loss thereof is reduced.

The present application further provides a laser machine automatic operating system. FIG. 2 is a block diagram illustrating one embodiment of the laser machine automatic operating system of the present application. Referring to FIG. 2, the laser machine automatic operating system of the present application comprises a laser machine 200 and a control system 210.

The laser machine 200 is employed to laser-process a wafer according to preset settings, and can generate record information. The record information is local information of the laser machine 200, and is related to operation circumstance of the wafer on the laser machine. Further, in this example, the record information at least includes inherent information of the wafer and operation information concerning the wafer completing laser operation.

The control system 210 is employed to acquire the record information from the laser machine 200, and to base on the record information to generate feature information. Moreover, the control system 210 is further employed to base on the feature information to judge the operation circumstance of the wafer on the laser machine 200, and to generate a control instruction.

Since the record information is the local information of the laser machine 200, there might be the circumstance in which the information cannot be identified by other programs or software, so the control system 210 analyzes the record information after the record information is acquired, to generate feature information identifiable by other programs or software.

Further, the control system 210 includes an automatic system 211 and a manufacturing execution system 212.

The automatic system 211 is communicable with the laser machine 200 for acquiring the record information from the laser machine 200. The automatic system 211 is communicable with the laser machine 200 via a communication protocol to hence transmit information.

The automatic system 211 is further capable of basing on the record information to generate the feature information. For instance, the automatic system 211 analyzes the record information and generate feature information with a preset format. The feature information with a preset format possesses certain regularity and can be identified by various program syntaxes, that is to say, the feature information can be identified by various programs and software, so that it can be utilized as identification information of the wafer. For instance, the automatic system 211 bases on the record information to generate feature information identifiable by the manufacturing execution system 212, so that the manufacturing execution system 212 can base on the feature information to judge whether the wafer should be laser-operated. The method to analyze the record information is a conventional method in this field of specialty, so this is not described in this context.

The automatic system 211 is further employed to send the control instruction of the manufacturing execution system 212 to the laser machine 200. In this embodiment, the automatic system 211 is an equipment automation programming (EAP) system.

The manufacturing execution system 212 is communicable with the automatic system 211, for instance, the manufacturing execution system 212 communicates with the automatic system 211 via a communication protocol.

The manufacturing execution system 212 can acquire the feature information, and base on the feature information to judge the operation circumstance of the wafer on the laser machine. The manufacturing execution system 212 can also generate the control instruction according to the judging result.

For instance, the manufacturing execution system 212 bases on the feature information to judge whether the wafer has completed operation on the laser machine; if the wafer has completed operation on the laser machine, the manufacturing execution system 212 issues an instruction to the automatic system 211 to skip over the laser machine to execute the next procedure, and the automatic system 211 forwards this instruction to the machine of the next procedure; if the wafer has not completed operation on the laser machine, the manufacturing execution system 212 issues a control instruction to the automatic system 211 to start the laser machine 200, the automatic system 211 forwards this control instruction to the laser machine 200, and the laser machine 200 is started to perform laser operation on the wafer.

Further, the manufacturing execution system 212 has a preset storage space for storing a database formed by the feature information. In this embodiment, the preset storage space is a storage location provided by the manufacturing execution system 212. For each wafer or every batch of wafers, after the manufacturing execution system 212 acquires the feature information, the feature information is stored in the preset storage space to form a database. The database is retrievable by the manufacturing execution system 212. In addition, if a problem occurs to the wafer, the user can further base on the record of the database to trace back to the history record of the wafer, so as to facilitate analysis of the problem.

Further, in this embodiment, the laser machine automatic operating system further comprises a comparing unit 213. The comparing unit 213 is employed to compare the inherent information of the wafer with the feature information in the database. If the inherent information matches with the feature information, that is to say, the inherent information is included in the feature information, it is then determined that the wafer has completed operation on the laser machine; if the inherent information does not match with the feature information, that is to say, the inherent information is not included in the feature information, it is then determined that the wafer has not completed operation on the laser machine.

The manufacturing execution system 212 bases on the comparing result to generate a control instruction. If it is determined that the wafer has completed operation on the laser machine, the manufacturing execution system 212 issues an instruction to the automatic system 211 to skip over the laser machine to execute the next procedure; if it is determined that the wafer has not completed operation on the laser machine, the manufacturing execution system 212 issues a control instruction to the automatic system 211 to start the laser machine 200, so as to control the laser machine to perform laser operation on the wafer.

Further, the laser machine automatic operating system further comprises a backing-up unit 214 capable of backing up the database. In the case data stored in the preset storage space 100 is lost, the data can be restored from the backing-up unit 214 into the preset storage space 100, thus avoiding misoperation of wafers, and greatly enhancing the acceptance rate of the wafers.

Described above are merely referred embodiments of the present application. As should be pointed out, it is further possible for persons ordinarily skilled in the art to make various improvements and modifications without departing from the principles of the present application, and all such improvements and modifications shall be regarded to also fall within the protection scope of the present application.

What is claimed is:

1. A laser machine automatic operating method, comprising:
(a) basing on feature information to judge whether a wafer has completed operation on a laser machine, if yes, skipping over the laser machine to perform the next procedure, if not, executing step (b);
(b) processing the wafer on the laser machine, wherein the laser machine generates record information, and the record information is related to operation information of the wafer on the laser machine; and
(c) acquiring the record information, and basing on the record information to generate feature information, the feature information serving as judging criteria in step (a).

2. The laser machine automatic operating method according to claim 1, wherein the feature information is stored in a preset storage space, and prior to the step of judging whether a wafer has performed operation on a laser machine is included a step of acquiring the feature information from the preset storage space.

3. The laser machine automatic operating method according to claim 1, wherein the feature information is stored in a preset storage space to form a database.

4. The laser machine automatic operating method according to claim 3, wherein step (a) further includes comparing inherent information of the wafer with feature information in the database: determining that the wafer has completed operation on the laser machine, if the inherent information matches with the feature information, and the feature information records that the wafer has completed entire operation; determining that the wafer has not completed operation on the laser machine, if the inherent information matches with the feature information, and the feature information records that the wafer has completed partial operation; and determining that the wafer has not completed operation on the laser machine, if the inherent information does not match with the feature information.

5. The laser machine automatic operating method according to claim 4, wherein the feature information at least includes the inherent information of the wafer and the operation information of the wafer on the laser machine.

6. The laser machine automatic operating method according to claim 5, wherein the inherent information of the wafer includes a batch number of the wafer.

7. The laser machine automatic operating method according to claim 3, wherein history record of the wafer is acquired according to the feature information.

8. The laser machine automatic operating method according to claim 3, wherein the database is backed up.

9. The laser machine automatic operating method according to claim 1, wherein the operation information is that the wafer has performed operation on the laser machine.

10. The laser machine automatic operating method according to claim 1, wherein the operation information is that the wafer has completed operation of laser phase on the laser machine.

11. A laser machine automatic operating system, comprising:
a laser machine, for laser-processing a wafer and capable of creating record information that is related to operation information of the wafer on the laser machine; and
a control system, for acquiring the record information from the laser machine, basing on the record information to generate feature information, basing on the feature information to judge whether the wafer has performed operation on the laser machine, and generating a control instruction.

12. The laser machine automatic operating system according to claim 11, wherein the control system includes:
an automatic system, communicable with the laser machine, for acquiring the record information from the laser machine, basing on the record information to generate the feature information, and sending a control instruction of a manufacturing execution system to the laser machine; and
a manufacturing execution system, communicable with the automatic system, for acquiring the feature information, basing on the feature information to judge whether the wafer has performed operation on the laser machine, and being capable of generating a control instruction.

13. The laser machine automatic operating system according to claim 12, wherein the manufacturing execution system has a preset storage space for storing a database formed by the feature information.

14. The laser machine automatic operating system according to claim 13, further comprising a backing-up unit for backing up the database.

15. The laser machine automatic operating system according to claim 12, further comprising a matching unit for matching inherent information of the wafer with feature information in a database, wherein the manufacturing execution system bases on a matching result to generate the control instruction.
